(19) United States
(12) Patent Application Publication
(10) Pub. No.: US 2024/0206339 A1
(43) Pub. Date: Jun. 20, 2024

(54) THERMOELECTRIC CONVERSION DEVICE AND THERMOELECTRIC CONVERSION MODULE

(71) Applicant: Sumitomo Electric Industries, Ltd., Osaka-shi, Osaka (JP)

(72) Inventors: Kotaro HIROSE, Osaka-shi, Osaka (JP); Masahiro ADACHI, Osaka-shi, Osaka (JP)

(73) Assignee: Sumitomo Electric Industries, Ltd., Osaka-shi, Osaka (JP)

(21) Appl. No.: 18/287,296

(22) PCT Filed: Feb. 4, 2022
(86) PCT No.: PCT/JP2022/004418

§ 371 Date: Oct. 18, 2023

(30) Foreign Application Priority Data
Apr. 20, 2021 (JP) 2021-070865

(51) Int. Cl. H10N 10/817; H10N 10/17; H10N 10/851

(52) U.S. Cl. CPC H10N 10/817; H10N 10/17; H10N 10/8556

(57) ABSTRACT

A thermoelectric conversion device includes a first electrode, a thermoelectric conversion material portion containing Si and Ge as constituent elements, a conductive joining member disposed in contact with the first electrode and the thermoelectric conversion material portion and joining the first electrode and the thermoelectric conversion material portion together, and a second electrode. The Si and the Ge contain amorphous phase and crystalline phase. The joining member contains at least one of Ag, Cu, Ti, and Sn or an alloy thereof as a major constituent. The thermoelectric conversion material portion includes a first layer containing the major constituent in an amount of 10 atm % or more and in contact with the joining member, and a second layer. The second layer has a degree of crystallinity of 40% by volume to 90% by volume.

### TECHNICAL FIELD

The present disclosure relates to a thermoelectric conversion device and a thermoelectric conversion module. This application claims priority based on Japanese Patent Application No. 2021-070865 filed on Apr. 20, 2021, and the entire contents of the Japanese patent application are incorporated herein by reference.

### BACKGROUND

PTL 1 discloses a thermoelectric module in which a plurality of thermoelectric elements are arranged on a wiring line conductor provided on a surface of a support substrate. The thermoelectric module disclosed in PTL 1 is characterized by providing a diffusion suppression layer for suppressing diffusion of a solder component on an end surface and a side surface of the thermoelectric element.

### PRIOR ART DOCUMENT

### Patent Literature

PTL 1: Japanese Unexamined Patent Application Publication No. 2005-50863

### SUMMARY OF INVENTION

A thermoelectric conversion device according to the present disclosure includes a first electrode, a thermoelectric conversion material portion containing Si and Ge as constituent elements and configured to convert heat into electricity, a conductive joining member disposed in contact with the first electrode and the thermoelectric conversion material portion and joining the first electrode and the thermoelectric conversion material portion together, and a second electrode disposed away from the first electrode and electrically connected to the thermoelectric conversion material portion. The Si and the Ge contain an amorphous phase and a crystalline phase. The joining member contains at least one of Ag, Cu, Ti, and Sn or an alloy thereof as a major constituent. The thermoelectric conversion material portion includes a first layer containing the major constituent in an amount of 10 atm % or more and in contact with the joining member, and a second layer in contact with the first layer. The second layer has a degree of crystallinity of 40% by volume to 90% by volume.

### BRIEF DESCRIPTION OF THE DRAWINGS

FIG. 1 is a schematic cross-sectional view showing a structure of a thermoelectric material element according to first embodiment.

FIG. 2 is an SEM image showing a part of the thermoelectric conversion device in which a first layer has a thickness D₁ of 20 μm.

FIG. 3 is an SEM image showing a part of a thermoelectric conversion device outside the scope of the present disclosure in which a first layer has thickness D₁ of 150 μm.

FIG. 4 is a graph showing results of measurements of a thermoelectric conversion material portion by Raman spectroscopy.

FIG. 5 is a graph showing a relationship between a degree of crystallinity and a thickness D₁ of the first layer.

FIG. 6 is a graph showing a relationship between a degree of crystallinity and a conductivity.

FIG. 7 is a diagram showing an example of a structure of a power generation module.

### DETAILED DESCRIPTION

### Problems to be Solved by Present Disclosure

A thermoelectric conversion device including a thermoelectric conversion material portion that converts heat into electricity is required to achieve high thermoelectric conversion efficiency by suppressing a decrease in thermoelectromotive force. Therefore, an object of the present disclosure is to provide a thermoelectric conversion device capable of realizing high thermoelectric conversion efficiency.

### Advantageous Effects of Present Disclosure

According to the thermoelectric conversion device, high thermoelectric conversion efficiency can be realized.

### DESCRIPTION OF EMBODIMENTS OF PRESENT DISCLOSURE

First, embodiments of the present disclosure will be listed and explained. A thermoelectric conversion device according to the present disclosure includes a first electrode, a thermoelectric conversion material portion containing Si and Ge as constituent elements and configured to convert heat into electricity, a conductive joining member disposed in contact with the first electrode and the thermoelectric conversion material portion and joining the first electrode and the thermoelectric conversion material portion together, and a second electrode disposed away from the first electrode and electrically connected to the thermoelectric conversion material portion. The Si and the Ge contain an amorphous phase and a crystalline phase. The joining member contains at least one of Ag, Cu, Ti, and Sn or an alloy thereof as a major constituent. The thermoelectric conversion material portion includes a first layer containing the major constituent in an amount of 10 atm % or more and in contact with the joining member, and a second layer in contact with the first layer. The second layer has a degree of crystallinity of 40% by volume to 90% by volume.

In a thermoelectric conversion device, electricity generated in a thermoelectric conversion material portion that converts heat (temperature difference) into electricity is output using a first electrode and a second electrode that are electrically connected to each other. Here, the inventors have considered the influence of the reaction at a joining portion where an electrode and the thermoelectric conversion material portion are joined to each other to inhibit the thermoelectric conversion efficiency when the thermoelectric conversion device is used at a high temperature of, for example, several hundred degrees ° C. The inventors have also found that when an amount of a reaction layer, in which a part of a joining member disposed between the electrode and the thermoelectric conversion material portion diffuses into the thermoelectric conversion material portion, increases, it causes an increase in power loss and a decrease in thermoelectromotive force. The inventors also focused on the fact that an intermediate layer for suppressing the diffusion of the joining member is required to satisfy high requirements, i.e., high adhesion to the thermoelectric conversion material, low contact electrical resistance, or low contact thermal resistance, and steps for forming the intermediate layer causes an increase in production cost. The inventors have made intensive studies to reduce the influence of the reaction layers as much as possible while preventing an increase in cost, and have completed the present invention.

Since the thermoelectric conversion device of the present disclosure includes the thermoelectric conversion material portion formed of SiGe (silicon germanium), high thermoelectric conversion efficiency may be achieved even when the thermoelectric conversion device is used at a high temperature. In addition, since the conductive joining member joining the first electrode and the thermoelectric conversion material portion together contains at least one of Ag, Cu, Ti, and Sn, or an alloy thereof as a major constituent, and thus has good conductivity. Therefore, it is possible to reduce power loss when electricity generated from heat (temperature difference) by the thermoelectric conversion material portion is transmitted to the first electrode. It is to be noted that the major constituent refers to an element of 20 atm % or more among elements constituting the joining member. When the thermoelectric conversion material portion and the joining member are alloyed with each other, the remainder obtained by subtracting constituent elements of the thermoelectric conversion material portion is regarded as 100 atm % of constituent elements of the joining member, and an element being 20 atm % or more is the major constituent.

The first layer included in the thermoelectric conversion material portion includes 10 atm % or more of a major constituent of the joining member. The second layer has a degree of crystallinity of 40% by volume to 90% by volume. In this configuration, it is possible to reduce a decrease in thermoelectromotive force due to the first layer becoming too thick and to reduce a decrease in conductivity in the thermoelectric conversion material portion by optimizing the degree of crystallinity. Therefore, according to the thermoelectric conversion device of the present disclosure, high thermoelectric conversion efficiency can be achieved.

In the thermoelectric conversion device, the first layer may have a thickness of 50 μm or less. In this configuration, it is possible to reduce a decrease in thermoelectromotive force and achieve high thermoelectric conversion efficiency.

In the thermoelectric conversion device, the thermoelectric conversion material portion may have a conductivity of more than 1000 S/m. In this configuration, it is possible to reduce a decrease in conductivity in the thermoelectric conversion material portion and to achieve high thermoelectric conversion efficiency.

In the thermoelectric conversion device, the degree of crystallinity may be 80% by volume or less. In this configuration, it is possible to reduce a decrease in thermoelectromotive force and achieve high thermoelectric conversion efficiency.

In the thermoelectric conversion device, the degree of crystallinity may be 50% by volume or more. In this configuration, high conductivity in the thermoelectric conversion material portion can be achieved. Therefore, higher thermoelectric conversion efficiency can be achieved.

In the thermoelectric conversion device, the joining member may contain Ag or Cu. Both Ag and Cu have high conductivity and thermal conductivity. Therefore, in this configuration, high thermoelectric conversion efficiency can be achieved more reliably.

A thermoelectric conversion module of the present disclosure includes a plurality of the thermoelectric conversion devices. The thermoelectric conversion module of the present disclosure includes a plurality of the thermoelectric conversion devices of the present disclosure, which are capable to achieve high thermoelectric conversion efficiency. In such the thermoelectric conversion module, high thermoelectric conversion efficiency can be achieved more reliably.

### DETAILS OF EMBODIMENTS OF PRESENT DISCLOSURE

Next, an embodiment of a thermoelectric conversion device of the present disclosure will be described with reference to the drawings. In the following drawings, the same or corresponding portions are denoted by the same reference numerals, and description thereof will not be repeated.

### First Embodiment

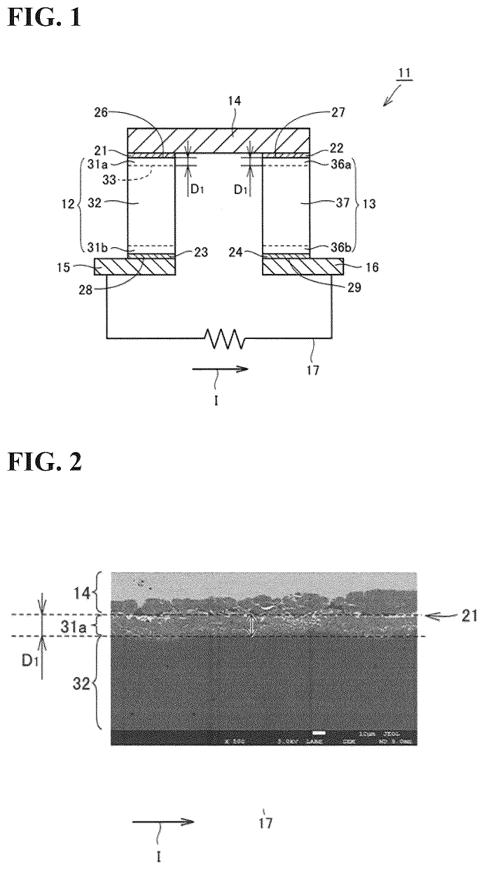

A thermoelectric material element according to the first embodiment, which is an embodiment of the present disclosure, will be described with reference to FIG. 1. FIG. 1 is a schematic cross-sectional view showing a structure of the thermoelectric material element according to the first embodiment. For ease of understanding, hatching indicating a cross section is partially omitted in FIG. 1.

FIG. 1 is a schematic view showing a structure of a thermoelectric conversion device (a power generation element) 11 which is a thermoelectric conversion device in the present embodiment. Referring to FIG. 1, thermoelectric conversion device 11 is a so-called π-type thermoelectric conversion device. Thermoelectric conversion device 11 of the present disclosure is used at relatively high temperatures, for example, in the temperature range of 300° ° C. to 800° C. Thermoelectric conversion device 11 includes a p-type thermoelectric conversion material portion 12 as a first thermoelectric conversion material portion, an n-type thermoelectric conversion material portion 13 as a second thermoelectric conversion material portion, a first electrode 14 disposed in a high temperature region, a second electrode 15 disposed in a low temperature region, a second electrode 16 also disposed in a low temperature region, conductive joining members 21, 22, 23, 24, and a wiring line 17. Contrary to the present embodiment, first electrode 14 may be disposed in a low temperature region and second electrodes 15 and 16 may be disposed in a high temperature region.

Thermoelectric conversion material portions 12 and 13 are formed of SiGe containing an amorphous phase and a crystalline phase. Thermoelectric conversion material portion 12 is formed of, for example, a thermoelectric conversion material whose component composition is adjusted to be of p-type conductivity. Thermoelectric conversion material portion 13 is formed of, for example, a thermoelectric conversion material whose component composition is adjusted to be of n-type conductivity.

Joining members 21, 22, 23, 24 having electrical conductivity contain at least one of Ag (silver), Cu (copper), Ti (titanium), and Sn (tin) as a major constituent. Specifically, as joining members 21, 22, 23, 24, for example, an Ag—Cu joining member containing Ag and Cu as major constituents, an Ag—Cu—Ti-based joining member containing Ag, Cu and Ti as major constituents, an Ag—Cu—Ti—Sn-based joining member containing Ag, Cu, Ti and Sn as major constituents, and a joining member formed of an inorganic binder containing Ag as a major constituent are used. The thickness of each of joining members 21, 22, 23, 24 may be equal to or greater than the surface roughness of thermoelectric conversion material portions 12, 13. In the present embodiment, each of joining members 21, 22, 23, 24 has a thickness of about 1 μm.

Thermoelectric conversion material portion 12 and thermoelectric conversion material portion 13 are disposed side by side with a gap therebetween. First electrode 14 is disposed to extend from a first end 26 of thermoelectric conversion material portion 12 to a first end 27 of thermoelectric conversion material portion 13. Joining member 21 is disposed in contact with first electrode 14 and thermoelectric conversion material portion 12. Joining member 21 joins first electrode 14 and thermoelectric conversion material portion 12 together, specifically first electrode 14 and first end 26 of thermoelectric conversion material portion 12. Joining member 22 is disposed in contact with first electrode 14 and thermoelectric conversion material portion 13. Joining member 22 joins first electrode 14 and thermoelectric conversion material portion 13 together, specifically first electrode 14 and first end 27 of thermoelectric conversion material portion 13. First electrode 14 is disposed to electrically connect first end 26 of thermoelectric conversion material portion 12 and first end 27 of thermoelectric conversion material portion 13. First electrode 14 is made of a conductive material, for example, Mo (molybdenum) metal.

Second electrode 15 is disposed away from each of first electrode 14 and other second electrode 16. Joining member 23 is disposed in contact with second electrode 15 and thermoelectric conversion material portion 12. Joining member 23 joins second electrode 15 and thermoelectric conversion material portion 12 together, specifically second electrode 15 and a second end 28 of thermoelectric conversion material portion 12. Second electrode 15 is made of a conductive material, for example, a metal such as Mo.

Second electrode 16 is disposed away from first electrode 14. Joining member 24 is disposed in contact with second electrode 16 and thermoelectric conversion material portion 13. Joining member 24 joins second electrode 15 and thermoelectric conversion material portion 13 together, specifically second electrode 15 and a second end 29 of thermoelectric conversion material portion 13. Second electrode 16 is made of a conductive material, for example, a metal such as Mo.

Wiring line 17 is made of a conductor such as a metal. Wiring line 17 electrically connects second electrode 15 and second electrode 16 via an electric resistance.

In thermoelectric conversion device 11, for example, when a temperature difference is formed such that a temperature of first end 26 of thermoelectric conversion material portion 12 and first end 27 of thermoelectric conversion material portion 13 is high and a temperature of second end 28 of thermoelectric conversion material portion 12 and second end 29 of thermoelectric conversion material portion 13 is low, p-type carriers (holes) move from first end 26 to second end 28 in thermoelectric conversion material portion 12. At this time, in thermoelectric conversion material portion 13, n-type carriers (electrons) move from first end 27 to second end 29. As a result, a current flows through wiring line 17 in an arrow I direction. In this way, in x-type thermoelectric conversion device 11, power generation by thermoelectric conversion utilizing a temperature difference is achieved. That is, thermoelectric conversion device 11 is a power generation element.

A specific configuration of thermoelectric conversion material portion 12 will be described. Thermoelectric conversion material portion 12 includes a first layer 31a, a second layer 32, and a third layer 31b. First layer 31a is in contact with joining member 21. First layer 31a includes 10 atm % or more of the major constituent of joining member 21. The upper limit of the major constituent is 90 atm %. First layer 31a is a region in which the major constituent of joining member 21 is partially diffused. A boundary 33 between first layer 31a and second layer 32 is indicated by a dashed line in FIG. 1. Third layer 31b is in contact with joining member 23. Third layer 31b includes 10 atm % or more of the major constituent of joining member 23. The upper limit of the major constituent is 90 atm %. Third layer 31b is a region in which the major constituent of joining member 23 is partially diffused. Second layer 32 is in contact with first layer 31a and third layer 31b. In the present embodiment, second layer 32 is sandwiched between first layer 31a and third layer 31b. Similar to thermoelectric conversion material portion 12, thermoelectric conversion material portion 13 includes a first layer 36a, a second layer 37, and a third layer 36b. First layer 36a is in contact with joining member 22. First layer 36a includes 10 atm % or more of the major constituent of joining member 22. The upper limit of the major constituent is 90 atm %. First layer 36a is a region in which the major constituent of joining member 22 is partially diffused. Third layer 36b is in contact with joining member 24. Third layer 36b includes 10 atm % or more of the major constituent of joining member 24. The upper limit of the major constituent is 90 atm %. Third layer 36b is a region in which the major constituent of joining member 24 is partially diffused. Second layer 37 is in contact with first layer 36a and third layer 36b.

First layers 31a, 36a has a thickness D₁ of 0.1 μm to 50 μm. With the structure in which the thickness of each of first layers 31a, 36a is 0.1 μm or more, joining members 21, 22 and thermoelectric conversion material portions 12, 13 can be joined to each other without separation. Thickness D₁ of first layers 31a and 36a may be 20 μm to 30 μm. In this way, the joining strength between joining member 21 and thermoelectric conversion material portion 12 can be increased and the loss of the thermoelectromotive force can be suppressed. In FIG. 1, the thicknesses of first layers 31a, 36a, and third layers 31b, 36b are shown thick from the viewpoint of easy understanding.

Thermoelectric conversion device 11 according to the first embodiment can be manufactured by, for example, the following manufacturing method. First, thermoelectric conversion material portions 12, 13 are manufactured. Specifically, Si (silicon) powder and Ge (germanium) powder are prepared. The mixing ratio of Si and Ge in element ratio is that Ge is 0.4 to 2.7, where Si is 1. The purity of each element is, for example, 99.99% or more. Further, about 1 atm % of powder of B or In is added as a dopant to the thermoelectric material for p-type thermoelectric conversion material portion 12. About 1 atm % of powder of P or Sb is added as a dopant to the thermoelectric material for n-type thermoelectric conversion material portion 13. Each of the prepared powder of p-type thermoelectric material and powder of n-type thermoelectric material is milled using a ball mill. Thereafter, pressure baking is performed. Specifically, thermoelectric conversion material portions 12, 13 as sintered body are obtained by baking in a temperature range of 400° ° C. to 900° C. by hot pressing.

Thermoelectric conversion material portions 12, 13 contain the amorphous phase and the crystalline phase. The degree of crystallinity, i.e., the volume ratio of the crystalline phase contained in thermoelectric conversion material portions 12, 13 can be controlled by, for example, adjusting the pressure and temperature of the hot pressing. Specifically, when a pressure of 400 MPa and a baking temperature of 700° C. are provided, thermoelectric conversion material portions 12, 13 having a degree of crystallinity of 99% by volume can be obtained. When a pressure of 300 MPa and a baking temperature of 700° C. are provided, thermoelectric conversion material portions 12, 13 having a degree of crystallinity of 95% by volume can be obtained. When a pressure of 200 MPa and a baking temperature of 700° ° C. are provided, thermoelectric conversion material portions 12, 13 having a degree of crystallinity of 83% by volume can be obtained. When a pressure of 400 MPa and a baking temperature of 600° C. are provided, thermoelectric conversion material portions 12, 13 having a degree of crystallinity of 76% by volume can be obtained. When a pressure of 400 MPa and a baking temperature of 500° C. are provided, thermoelectric conversion material portions 12, 13 having a degree of crystallinity of 50% by volume can be obtained. When a pressure of 300 MPa and a baking temperature of 400° C. are provided, thermoelectric conversion material portions 12, 13 having a degree of crystallinity of 38% by volume can be obtained.

Next, obtained thermoelectric conversion material portions 12, 13 are cut by a wire saw into a rectangular parallelepiped shape of several mm square. Then, for example, Ag—Cu-based joining members 21, 22, 23, 24 are applied to a surface of the first end and a surface of the second end opposite to the first end, and first electrode 14, and second electrodes 15, 16 made of Mo are attached thereto. Then, thermoelectric conversion material portions 12, 13 are respectively joined together to first electrode 14, and second electrodes 15, 16 by joining members 21, 22, 23, 24 by baking at a temperature of 100° C. to 500° ° C. to obtain thermoelectric conversion device 11 according to the present disclosure.

In the present embodiment, since thermoelectric conversion device 11 includes thermoelectric conversion material portions 12, 13 formed of SiGe (silicon germanium), high thermoelectric conversion efficiency can be achieved even when thermoelectric conversion device 11 is used at a high temperature. In addition, joining members 21 and 22 having conductivity, which join first electrode 14 and thermoelectric conversion material portions 12, 13 together, contain at least one of Ag, Cu, Ti, and Sn as a major constituent, and thus have good conductivity. Therefore, it is possible to reduce power loss when electricity generated from heat (temperature difference) by thermoelectric conversion material portions 12, 13 is transmitted to first electrode 14.

In addition, thickness D₁ of first layers 31a, 36a included in thermoelectric conversion material portions 12, 13 and including 10 atm % or more of the major constituent of joining members 21, 22 is 0.1 μm to 50 μm. In addition, thermoelectric conversion material portions 12, 13, specifically, second layer 32, 37 have a degree of crystallinity of 40% by volume to 90% by volume. Therefore, it is possible to reduce a decrease in thermoelectromotive force due to first layer 31a becoming too thick, and to reduce a decrease in conductivity in thermoelectric conversion material portions 12, 13 by optimizing the degree of crystallinity. Therefore, according to thermoelectric conversion device 11 of the present disclosure, high thermoelectric conversion efficiency can be realized.

Regarding a measurement of thickness D₁ of first layer 31a, the region including first electrode 14, joining member 21, and thermoelectric conversion material portion 12 was polished to obtain the cross section shown in FIG. 1, and thickness D₁ of first layer 31a was measured by SEM (Scanning Electron Microscope)/EDX (Energy dispersive X-ray spectroscopy). The concentration of the major constituent of joining member 21 can be measured by EDX. The thickness of third layer 31b and the concentration of the major constituent of joining member 22 can also be measured in the same manner.

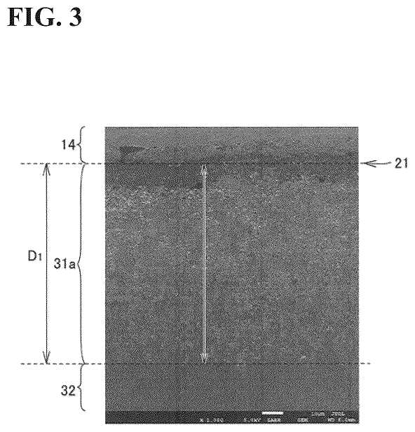

FIG. 2 is an SEM image showing a portion of a thermoelectric conversion device in which first layer 31a has a thickness D₁ of 20 μm (corresponding to a degree of crystallinity of 76% by volume described below). FIG. 3 is an SEM image showing a portion of a thermoelectric conversion device in which first layer 31a has a thickness D₁ of 150 μm (corresponding to a degree of crystallinity of 99% by volume described below) and is outside the scope of the present disclosure. FIGS. 2 and 3 show a portion of the region where first layer 31a is located. FIGS. 2 and 3 also show regions corresponding to first electrode 14, joining member 21, first layer 31a and second layer 32. For the thermoelectric conversion device shown in FIG. 2, first layer 31a is thin, and has a thickness of 0.1 μm to 50 μm. On the other hand, for the thermoelectric conversion device shown in FIG. 3, first layer 31a is thick, and has a thickness more than 50 μm.

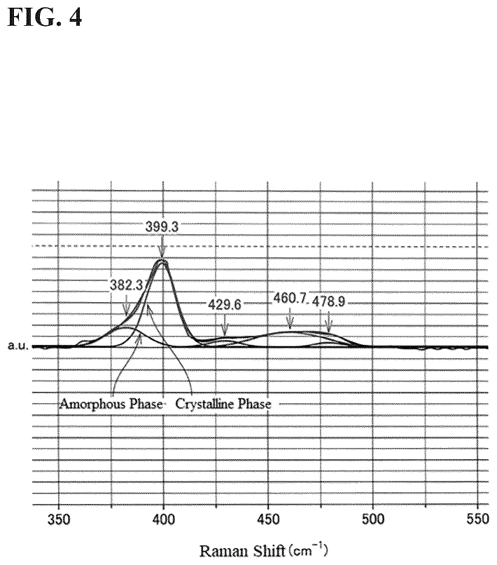

The degree of crystallinity of second layer 32 was derived using Raman spectroscopy. Here, derivation of the degree of crystallinity will be described. FIG. 4 is a graph showing the results of measurements of thermoelectric conversion material portion 12 by Raman spectroscopy. In FIG. 4, the horizontal axis represents Raman shift (cm⁻¹). The vertical axis represents an arbitrary unit (a. u.).

HORIBA LabRam HR-PL was used as a device for performing Raman spectroscopy. As the measurement conditions, the laser wave length was 532 nm and the laser power was 2.5 mW. FIG. 4 shows the results obtained by measuring second layer 32 at five points and calculating the average thereof. As an analysis condition, a peak near 400 cm⁻¹ was analyzed. In the analysis, the waveform f(x) calculated using five pseudo-Voigt functions was fitted. The pseudo-Voigt function F(x) is expressed by the following equation 1.

$$F ( x ) = {A}_{F} \frac{m}{π} [ \frac{{W}_{f}}{{( x - {x}_{f} )}^{2} + {W}_{f}^{2}} ] + {A}_{F} \frac{1 - m}{\sqrt{2 π {W}_{f}}} exp [ - \frac{{( x - {x}_{f} )}^{2}}{2 {W}_{f}^{2}} ] \qquad [ Equation 1 ]$$

The parameters A_{f}, W_{f}, x_{f}, and m of the five pseudo-Voigt functions F(x) are shown in Table 1. For convenience, notations of the parameters are the same in the five pseudo-Voigt functions F(x), but values of the parameters are different from each other. An initial value of a variable parameter which is not described in the initial condition is 0. For example, an initial value of A_{f} of the pseudo-Voigt function No. 1 is a value obtained by obtaining f(x_{f}) at x_{f}=380 cm⁻¹ of the calculated waveform f(x) and dividing it by 2. Each of the parameters is optimized by the least squares method, and the pseudo-Voigt function is integrated to obtain the area. The degree of crystallinity is calculated by S₂/(S₁+S₂), wherein the area of the pseudo-Voigt function No. 1 corresponding to SiGe in the amorphous phase is S₁ and the area of the pseudo-Voigt function No. 2 corresponding to SiGe in the crystalline phase is S₂.

TABLE 1

| Pseudo-Voigt | Parameter | Parameter | |
|---|---|---|---|
| Function No. | (constant) | (variable) | Initial Condition |
| 1 | m = 0 | A [symbol] , W [symbol] , x [symbol] | x [symbol] = 380, A [symbol] = [symbol] (x [symbol] )/2 |
| 2 | W [symbol] = 16. [symbol] 7 | A [symbol] , [symbol] , m | x [symbol] = 400, A [symbol] = [symbol] (x [symbol] )/2 |
| 3 | m = 0. [symbol] | A [symbol] , W [symbol] , x [symbol] | x [symbol] = 430, A [symbol] = [symbol] (x [symbol] )/2 |
| 4 | None | A [symbol] , W [symbol] , x [symbol] , m | x [symbol] = 460, A [symbol] = [symbol] (x [symbol] )/2 |
| 5 | None | A [symbol] , W [symbol] , x [symbol] , m | x [symbol] = 480, A [symbol] = [symbol] (x [symbol] )/2 |

[symbol]

indicates data missing or illegible when filed

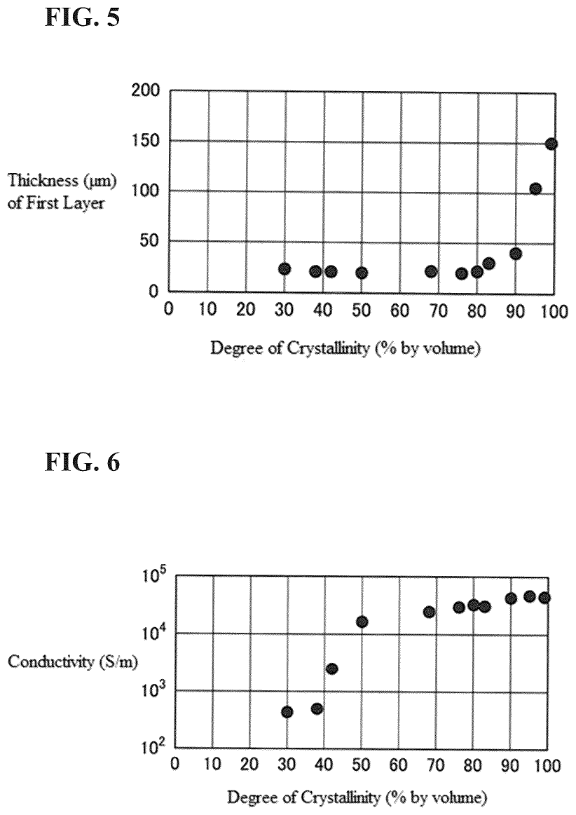

FIG. 5 is a graph showing a relationship between degree of crystallinity of second layer 32 and thickness D₁ of first layer 31a. In FIG. 5, the horizontal axis represents degree of crystallinity (% by volume) and the vertical axis represents thicknesses D₁ (μm) of first layer 31a. FIG. 6 is a graph showing a relationship between degree of crystallinity and conductivity. In FIG. 6, the horizontal axis represents degree of crystallinity (% by volume) and the vertical axis represents conductivity (S/m). Table 2 shows values of thicknesses D₁ and conductivities of first layers 31a corresponding to degrees of crystallinity.

TABLE 2

| Degree of Crystallinity | Thickness (μm) of | Conductivity |
|---|---|---|
| (% by volume) | First Layer | (S/m) |
| 30 | 23 | 435 |
| 38 | 21 | 493 |
| 42 | 21 | 2439 |
| 50 | 20 | 16667 |
| 68 | 22 | 24691 |
| 76 | 20 | 30303 |
| 80 | 22 | 32258 |
| 83 | 30 | 31250 |
| 90 | 40 | 43478 |
| 95 | 105 | 47619 |
| 99 | 150 | 45455 |

A conductivity was measured using a thermoelectric characteristic measuring device (manufactured by Ozawa Scientific Co., Ltd., RZ2001i). A measurement method is as follows. First, thermoelectric conversion material portion 12 is fixed to a pair of quartz jigs so as to be bridged. Two metal probes connected to a positive electrode and a negative electrode of an ammeter are brought into contact with first electrode 14 and second electrode 15, respectively. Two metal probes connected to a positive electrode and a negative electrode of a voltmeter are connected to a surface of thermoelectric conversion material portion 12. At this time, the contact points of the four probes are arranged on a straight line. Thereafter, a current is supplied to the current source, and the amount of voltage drop is measured by an internal voltmeter. Thus, a resistance value of thermoelectric conversion material portion 12 is measured by the four terminal method. Conductivity is derived from the measured resistance value.

Referring to FIGS. 5 and 6, by setting the degree of crystallinity of second layer 32 to 90% by volume or less, thickness D₁ of first layer 31a can be set to 50 μm or less. Furthermore, by setting the degree of crystallinity of second layer 32 to 80% by volume or less, thickness D₁ of first layer 31a can be set to 30 μm or less. First layer 31a has a higher thermal resistance and a smaller thermoelectromotive force than second layer 32. Therefore, by reducing the film thickness of first layer 31a in this way, it is possible to further reduce a decrease in the thermoelectromotive force and achieve higher thermoelectric conversion efficiency.

By setting the degree of crystallinity of second layer 32 to 40% by volume or more, the conductivity can be made larger than 1000 S/m. Further, by setting the degree of crystallinity of second layer 32 to 50% by volume or more, the conductivity can be made larger than 10000 S/m. In this way, high conductivity can be achieved in thermoelectric conversion material portion 12. Therefore, higher thermoelectric conversion efficiency can be achieved.

The configuration and characteristics of first layer 31a are similarly applied to third layer 31b, and the same effect is obtained. That is, third layer 31b has a thickness D₃ of 0.1 μm to 50 μm. Third layer 31b may have a thickness D₃ of 20 μm to 30 μm.

As described above, according to thermoelectric conversion device 11 of the present disclosure, high thermoelectric conversion efficiency can be realized.

In the above embodiment, joining members 21, 22, 23, 24 may contain Ag or Cu. Both Ag and Cu have high conductivity and thermal conductivity. Therefore, by doing so, high thermoelectric conversion efficiency can be realized more reliably.

Although the x-type thermoelectric conversion device has been described as an example of the thermoelectric conversion device of the present disclosure in the above embodiment, the thermoelectric conversion device of the present disclosure is not limited to this. The thermoelectric conversion device of the present disclosure may be a thermoelectric conversion device having other structures, for example, an I-type (unileg type) thermoelectric conversion device. Further, in the above-described embodiment, at least one of thermoelectric conversion material portions 12, 13 may have the above-described configuration.

### Second Embodiment

By electrically connecting a plurality of x-type thermoelectric conversion devices 11, a power generation module as a thermoelectric conversion module can be obtained. A power generation module 41, which is a thermoelectric conversion module of the present embodiment, has a structure in which a plurality of x-type thermoelectric conversion devices 11 are connected in series.

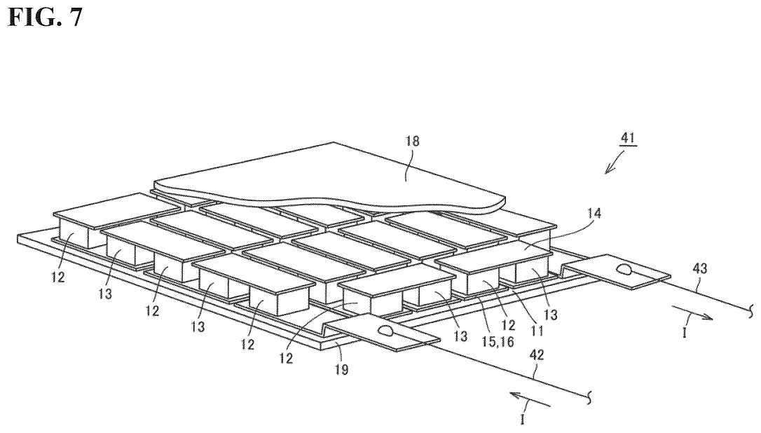

FIG. 7 a diagram showing an example of a structure of a power generation module. Power generation module 41 of the present embodiment includes a plurality of thermoelectric conversion devices 11, a first insulator substrate 19, and a second insulator substrate 18. Thermoelectric conversion device 11 includes a p-type thermoelectric conversion material portion 12, an n-type thermoelectric conversion material portion 13, a first electrode 14, second electrodes 15 and 16, a joining member (not shown) for joining thermoelectric conversion material portion 12 and first electrode 14 together, a joining member (not shown) for joining thermoelectric conversion material portion 13 and first electrode 14 together, a joining member (not shown) for joining thermoelectric conversion material portion 12 and second electrode 15 together, and a joining member (not shown) for joining thermoelectric conversion material portion 13 and second electrode 16 together. First insulator substrate 19 and second insulator substrate 18 are made of ceramic such as alumina.

P-type thermoelectric conversion material portions 12 and n-type thermoelectric conversion material portions 13 are alternately disposed. Second electrodes 15, 16 are joined to p-type thermoelectric conversion material portion 12 and n-type thermoelectric conversion material portion 13 by joining members respectively. First electrode 14 is joined to p-type thermoelectric conversion material portion 12 and n-type thermoelectric conversion material portion 13 by joining member. P-type thermoelectric conversion material portion 12 and thermoelectric conversion material portion 13 adjacent to one side of thermoelectric conversion material portion 12 are connected by first electrode 14. In addition, p-type thermoelectric conversion material portion 12 and n-type thermoelectric conversion material portion 13 adjacent to the other side of thermoelectric conversion material portion 12 are connected by second electrodes 15, 16. In this configuration, all p-type thermoelectric conversion material portions 12 and n-type thermoelectric conversion material portions 13 are connected in series.

Second insulator substrate 18 is disposed on a side of a main surface opposite to a side on which plate-shaped second electrodes 15, 16 are in contact with p-type thermoelectric conversion material portions 12 and n-type thermoelectric conversion material portions 13. One second insulator substrate 18 is disposed for a plurality of (all) second electrodes 15, 16. First insulator substrate 19 is disposed on a side opposite to a side on which plate-shaped first electrodes 14 are in contact with p-type thermoelectric conversion material portions 12 and n-type thermoelectric conversion material portions 13. One first insulator substrate 19 is disposed for a plurality of (all) first electrodes 14.

Each of wiring lines 42 and 43 is connected to first electrode 14 or second electrode 15 or 16 joined to p-type thermoelectric conversion material portion 12 or n-type thermoelectric conversion material portion 13 located at both ends of p-type thermoelectric conversion material portions 12 and n-type thermoelectric conversion material portions 13 connected in series. When a temperature difference is formed so that a side of first insulator substrate 19 is at a high temperature and a side of second insulator substrate 18 is at a low temperature, a current flows in arrow I direction by p-type thermoelectric conversion material portions 12 and n-type thermoelectric conversion material portions 13 connected in series as in the case of thermoelectric conversion device 11. In this way, power generation by thermoelectric conversion using a temperature difference is achieved in power generation module 41.

According to such power generation module 41, since a plurality of thermoelectric conversion devices 11 of the present disclosure that are capable of realizing high thermoelectric conversion efficiency are included, high thermoelectric conversion efficiency may be achieved.

It should be understood that the embodiments disclosed herein are illustrative in all respects and are not restrictive in any respect. The scope of the present invention is defined not by the above description but by the claims, and is intended to include all modifications within the meaning and scope equivalent to the claims.

### REFERENCE SIGNS LIST

11 thermoelectric conversion device
12, 13 thermoelectric conversion material portion
14 first electrode
15, 16 second electrode
17, 42, 43 wiring line
18 second insulator substrate
19 first insulator substrate
21, 22, 23, 24 joining member
26, 27, 28, 29 end
31a, 36a first layer
31b, 36b third layer
32, 37 second layer
33 boundary
41 power generation module (thermoelectric conversion module)
D₁ thickness
I arrow

1. A thermoelectric conversion device comprising:
a first electrode;
a thermoelectric conversion material portion containing Si and Ge as constituent elements and configured to convert heat into electricity;
a conductive joining member disposed in contact with the first electrode and the thermoelectric conversion material portion and joining the first electrode and the thermoelectric conversion material portion together; and
a second electrode disposed away from the first electrode and electrically connected to the thermoelectric conversion material portion,
wherein the Si and the Ge contain an amorphous phase and a crystalline phase,
the joining member contains at least one of Ag, Cu, Ti, and Sn or an alloy thereof as a major constituent,
the thermoelectric conversion material portion includes
a first layer containing the major constituent in an amount of 10 atm % or more and in contact with the joining member, and
a second layer in contact with the first layer, and
the second layer has a degree of crystallinity of 40% by volume to 90% by volume.

2. The thermoelectric conversion device according to claim 1, wherein the first layer has a thickness of 50 μm or less.

3. The thermoelectric conversion device according to claim 1, wherein the thermoelectric conversion material portion has a conductivity of more than 1,000 S/m.

4. The thermoelectric conversion device according to claim 1, wherein the degree of crystallinity is 80% by volume or less.

5. The thermoelectric conversion device according to claim 1, wherein the degree of crystallinity is 50% by volume or more.

6. The thermoelectric conversion device according to claim 1, wherein the joining member contains Ag or Cu.

7. (canceled)

8. The thermoelectric conversion device according to claim 2, wherein the joining member contains Ag or Cu.

9. The thermoelectric conversion device according to claim 3, wherein the joining member contains Ag or Cu.

10. The thermoelectric conversion device according to claim 4, wherein the joining member contains Ag or Cu.

11. The thermoelectric conversion device according to claim 5, wherein the joining member contains Ag or Cu.

12. A thermoelectric conversion module comprising a plurality of the thermoelectric conversion devices according to claim 1.

13. A thermoelectric conversion module comprising a plurality of the thermoelectric conversion devices according to claim 2.

14. A thermoelectric conversion module comprising a plurality of the thermoelectric conversion devices according to claim 3.

15. A thermoelectric conversion module comprising a plurality of the thermoelectric conversion devices according to claim 4.

16. A thermoelectric conversion module comprising a plurality of the thermoelectric conversion devices according to claim 5.

17. A thermoelectric conversion module comprising a plurality of the thermoelectric conversion devices according to claim 6.
